(19) United States
(12) Patent Application Publication
(10) Pub. No.: US 2014/0343876 A1
(43) Pub. Date: Nov. 20, 2014

(54) ELECTRIC STORAGE SYSTEM

(71) Applicants: Kenji Takahashi, Toyota-shi (JP); Yuji Nishi, Nagoya-shi (JP)

(72) Inventors: Kenji Takahashi, Toyota-shi (JP); Yuji Nishi, Nagoya-shi (JP)

(73) Assignee: TOYOTA JIDOSHA KABUSHIKI KAISHA, Toyota-shi, Aichi (JP)

(21) Appl. No.: 13/577,303

(22) PCT Filed: Feb. 1, 2012
(86) PCT No.: PCT/JP2012/000692

§ 371 Date: Aug. 6, 2012

(51) Int. Cl. G01R 31/36

(52) U.S. Cl. CPC G01R 31/3648; G01R 31/362
USPC 702/63

(57) ABSTRACT

Each of the electric storage elements has a current interrupt device interrupting a current path within the electric storage element. The controller uses the voltage detected by the voltage sensor to calculate the estimated value of a current passing through the electric storage block having a plurality of electric storage elements connected in parallel. The controller uses the correspondence between a first ratio and a second ratio to determine whether or not the current interrupt device is in an interrupt state. The first ratio is the ratio between the estimated current value and the reference value of a current passing through the electric storage block. The second ratio is the ratio between the total number of the electric storage elements constituting the electric storage block and the total number of the current interrupt devices not in the interrupt state.

### TECHNICAL FIELD

The present invention relates to an electric storage system in which the operational state of a current interrupt device is determined in an electric storage block including a plurality of electric storage elements connected in parallel and each having the current interrupt device.

### BACKGROUND ART

In an assembled battery described in Patent Document 1 having a plurality of cells connected in parallel, a fuse is connected to each of the cells connected in parallel. Upon the passage of an excessive current, the fuse blows to break a current path. In a technology described in Patent Document 2, the operation of a current interrupting mechanism included in a battery is detected on the basis of a change in internal resistance of the battery.

### PRIOR ART DOCUMENT

### Patent Documents

[Patent Document 1] Japanese Patent Laid-Open No. 05 (1993)-275116

[Patent Document 2] Japanese Patent Laid-Open No. 2008-182779

[Patent Document 3] Japanese Patent Laid-Open No. 2011-135657

### SUMMARY OF THE INVENTION

### Problems to be Solved by the Invention

In the configuration including the plurality of cells connected in parallel, the value of a current passing through the cell in which the current interrupt device is not operated is changed in accordance with the number of operating current interrupt devices. Specifically, as the number of operating current interrupt devices is increased, the value of a current passing through the cell in which the current interrupt device is not operated is increased to add a current load on the cell. Thus, it is necessary to sense the operation of the current interrupt device in view of control of charge and discharge of the cell. The present invention achieves the sensing of the operation of the current interrupt device by using a method different from the technology described in Patent Document 2.

### Means for Solving the Problems

According to a first aspect, the present invention provides an electric storage system including an electric storage block having a plurality of electric storage elements connected in parallel, a voltage sensor detecting the voltage of the electric storage block, and a controller determining the state of the electric storage block. Each of the electric storage elements has a current interrupt device interrupting a current path within the electric storage element. The controller uses the voltage detected by the voltage sensor to calculate the estimated value of a current passing through the electric storage block. The controller also uses the correspondence between a first ratio and a second ratio to determine whether or not the current interrupt device is in an interrupt state. The first ratio is the ratio between the estimated current value and the reference value of a current passing through the electric storage block. The second ratio is the ratio between the total number of the electric storage elements constituting the electric storage block and the total number of current interrupt devices not in the interrupt state.

The particular correspondence between the first ratio and the second ratio can be used to determine whether or not the current interrupt device is in the interrupt state. The first ratio can be calculated from the estimated current value and the reference current value. In the second ratio, the total number of the electric storage elements constituting the electric storage block is previously known. Thus, the total number of the current interrupt devices not in the interrupt state can be calculated from the correspondence between the first ratio and the second ratio. The total number of the current interrupt devices not in the interrupt state can be subtracted from the total number of the electric storage elements constituting the electric storage block to specify the total number of the current interrupt devices in the interrupt state (the number of interrupts). When the number of interrupts is changed from zero to a positive integer, it can be determined that one of the current interrupt devices is rendered in the interrupt state.

In using the current sensor to detect the value of the current passing through the electric storage block, the current value detected by the current sensor (detected current value) can be used as the reference current value. The estimated current value is calculated from the detected voltage, and the detected voltage depends on the number of interrupts. When the current interrupt device is rendered in the interrupt state, no current passes through the electric storage element having the current interrupt device in the interrupt state, so that the voltage of that electric storage block is changed more easily than the voltage of the electric storage block which does not include any current interrupt device in the interrupt state.

Thus, the estimated current value calculated from the detected voltage is the value reflecting the number of interrupts. On the other hand, the detected current value is the value of a current passing through the electric storage block and does not depend on the number of interrupts. In other words, since the detected current is not changed even when the current interrupt device is rendered in the interrupt state, the detected current value can be used as the reference current value in determining the interrupt state of the current interrupt device.

Since the first ratio calculated from the estimated current value and the detected current value has the correspondence with the second ratio, the correspondence can be used to determine that the current interrupt device is in the interrupt state or to determine the number of the current interrupt devices in the interrupt state.

When a plurality of electric storage blocks are connected in series, the estimated current value in the electric storage block which does not include any current interrupt device in the interrupt state (referred to as a normal electric storage block) can be used as the reference current value. As described above, the detected voltage used in calculating the estimated current value depends on the number of interrupts. Thus, the use of the estimated current value in the normal electric storage block as the reference current value to be compared can establish the particular correspondence between the first ratio and the second ratio. The correspondence can be used to determine that the current interrupt device is in the interrupt state or to determine the number of the current interrupt devices in the interrupt state.

Information indicating the correspondence between each of the electric storage blocks and the total number of the current interrupt devices in the interrupt state can be stored in a memory. The information stored in the memory can be referenced to specify the electric storage block which does not include any current interrupt device in the interrupt state. The estimated current value in the specified electric storage block can be used as the reference current value. When two or more of the electric storage blocks do not include any current interrupt device in the interrupt state, the median of the estimated current values in these electric storage blocks can be used as the reference current value. Alternatively, the value calculated by averaging two or more of the estimated current values included in a predetermined range with the median as the reference can be used as the reference current value.

The controller can determine that the current interrupt device is in the interrupt state when the following expression (I) is satisfied:

$$\frac{I 1}{I 2} \times \frac{N - m}{N} = 1 \qquad ( I )$$

In the expression (I), I1 represents the estimated current value, I2 represents the reference current value, N represents the total number of the electric storage elements constituting the electric storage block, and m represents the total number of the current interrupt devices in the interrupt state.

The value of I1/I2 is equal to the value of N/(N−m). Thus, the value of the I1/I2 can be multiplied by the inverse of the value N/(N−m) to provide a calculated value equal to one. The condition can be checked to determine that the current interrupt device is in the interrupt state.

A fuse, a PTC element, or a current interrupting valve can be used as the current interrupt device. The fuse breaks the current path through blowing. The PTC element breaks the current path through an increased resistance associated with a temperature rise. The current interrupting valve is deformed upon an increased internal pressure of the electric storage element to break the current path.

According to a second aspect, the present invention provides a method of determining a state of an electric storage block having a plurality of electric storage elements connected in parallel. Each of the electric storage elements has a current interrupt device interrupting a current path within the electric storage element. First, a voltage detected by a voltage sensor is used to calculate the estimated value of a current passing through the electric storage block. Then, the correspondence between the first ratio and the second ratio described in the first aspect of the present invention can be used to determine whether or not the current interrupt device is in an interrupt state. The second aspect of the present invention can achieve the same advantages as those in the first aspect of the present invention.

### BRIEF DESCRIPTION OF THE DRAWINGS

FIG. 1 A diagram showing the configuration of a battery system.

FIG. 2 A diagram showing the configuration of an assembled battery.

FIG. 3 A diagram showing the configuration of a cell.

FIG. 4 A flow chart showing processing of specifying the number of interrupts in Embodiment 1.

FIG. 5 A map representing the correspondence between a battery block and the number of interrupts.

FIG. 6 A flow chart showing processing of specifying the number of interrupts in Embodiment 2.

FIG. 7 A flow chart showing processing of specifying the number of interrupts in a modification of Embodiment 2.

### EMBODIMENTS OF THE INVENTION

Embodiments of the present invention will hereinafter be described.

### Embodiment 1

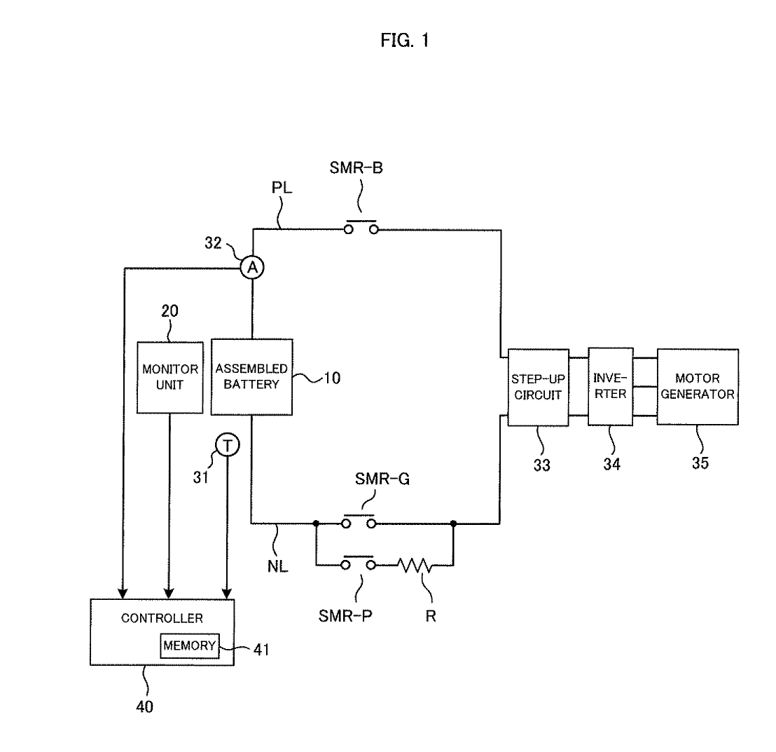

A battery system (corresponding to an electric storage system) which is Embodiment 1 of the present invention is described with reference to FIG. 1. FIG. 1 is a diagram showing the configuration of the battery system. The battery system of the present embodiment is mounted on a vehicle.

Examples of the vehicle include a hybrid vehicle and an electric vehicle. The hybrid vehicle includes an engine or a fuel cell in addition to an assembled battery, later described, as the power source for running of the vehicle. The electric vehicle includes only the assembled battery, later described, as the power source for running of the vehicle.

A system main relay SMR-B is provided on a positive electrode line PL connected to a positive electrode terminal of the assembled battery 10. The system main relay SMR-B is switched between ON and OFF in response to a control signal from a controller 40. A system main relay SMR-G is provided on a negative electrode line NL connected to a negative electrode terminal of the assembled battery 10. The system main relay SMR-G is switched between ON and OFF in response to a control signal from the controller 40.

The system main relay SMR-G is connected in parallel to a system main relay SMR-P and a current limiting resistor R. The system main relay SMR-P and the current limiting resistor R are connected in series. The system main relay SMR′-P is switched between ON and OFF in response to a control signal from the controller 40. The current limiting resistor R is used to prevent an inrush current from passing in connecting the assembled battery 10 to a load (specifically, a step-up circuit 32, later described).

In connecting the assembled battery 10 to the load, the controller 40 first switches the system main relays SMR-B and SMR-P from OFF to ON. This can pass a current through the current limiting resistor R to prevent the inrush current from passing.

Next, the controller 40 switches the system main relay SMR-G from OFF to ON and then switches the system main relay SMR-P from ON to OFF. This completes the connection between the assembled battery 10 and the load to render the battery system shown in FIG. 1 operational (“Ready-On”). On the other hand, in interrupting the connection between the assembled battery 10 and the load, the controller 40 first switches the system main relays SMR-B and SMR-G from ON to OFF. This stops the operation of the battery system shown in FIG. 1.

The step-up circuit 33 increases an output voltage from the assembled battery 10 and outputs power after increasing voltage to an inverter 34. The step-up circuit 33 also reduces an output voltage from the inverter 34 and outputs power after reducing voltage to the assembled battery 10. The step-up circuit 33 operates in response to a control signal from the controller 40. While the step-up circuit 33 is used in the battery system of the present embodiment, the step-up circuit 33 may be omitted.

The inverter 34 converts a DC power output from the step-up circuit 33 into an AC power and outputs the AC power to a motor generator 35. The inverter 34 converts an AC power generated by the motor generator 35 into a DC power and outputs the DC power to the step-up circuit 33. A three-phase AC motor can be used as the motor generator 35, for example.

The motor generator 35 receives the AC power from the inverter 34 to generate a kinetic energy for running of the vehicle. In using the output power from the assembled battery 10 to run the vehicle, the kinetic energy generated by the motor generator 35 is transferred to wheels.

For decelerating or stopping the vehicle, the motor generator 35 converts a kinetic energy generated in braking of the vehicle into an electric energy (AC power). The inverter 34 converts the AC power generated by the motor generator 35 into an AC power and outputs the AC power to the step-up circuit 33. The step-up circuit 33 outputs the power from the inverter 34 to the assembled battery 10. Thus, the regenerative power can be stored on the assembled battery 10.

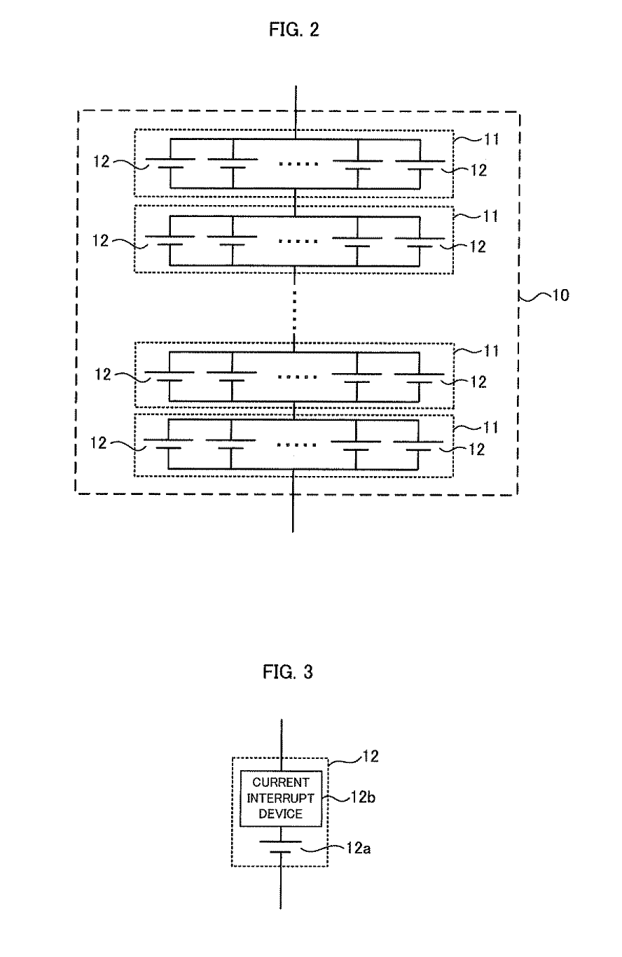

FIG. 2 shows the configuration of the assembled battery 10. The assembled battery 10 has a plurality of battery blocks (corresponding to electric storage blocks) 11 connected in series. The series connection of the plurality of battery blocks 11 can ensure the output voltage of the assembled battery 10. The number of the battery blocks 11 can be set as appropriate by taking account of the voltage required of the assembled battery 10.

Each of the battery blocks 11 has a plurality of cells (corresponding to electric storage elements) 12 connected in parallel. The parallel connection of the plurality of cells 12 can increase the full charge capacity of the battery block 11 (assembled battery 10) to extend the running distance of the vehicle with the output from the assembled battery 10. The number of the cells 12 constituting each of the battery blocks 11 can be set as appropriate by taking account of the full charge capacity required of the assembled battery 10. The number of the cells 12 constituting the battery block 11 is represented by N.

Since the plurality of battery blocks 11 are connected in series, the same current passes through each of the battery blocks 11. Since the plurality of cells 12 are connected in parallel in each of the battery blocks 11, the value of a current passing through each of the cells 12 is calculated by dividing the value of the current passing through the battery block 11 by the number (total number) of the cells 12 constituting the battery block 11. Specifically, assuming that the total number of the cells 12 constituting the battery block 11 is N and the value of the current passing through the battery block 11 is Is, the value of the current passing through each of the cells 12 is calculated from Is/N. It is assumed herein that no variations occur in internal resistance among the plurality of cells 12 constituting the battery block 11.

A secondary battery such as a nickel metal hydride battery and a lithium-ion battery can be used as the cell 12. An electric double layer capacitor can be used instead of the secondary battery. For example, a 18650-type battery can be used as the cell 12. The 18650-type battery is of a so-called cylindrical type with a diameter of 18 mm and a length of 65.0 mm. The cylindrical battery has a battery case of cylindrical shape and a power-generating element performing charge and discharge is housed in the battery case. The configuration of the power-generating element is described later.

As shown in FIG. 3, the cell 12 has a power-generating element 12a and a current interrupt device 12b. The power-generating element 12a and the current interrupt device 12b are housed in a cell case providing the exterior of the cell 12. The power-generating element 12a is an element performing charge and discharge and has a positive electrode plate, a negative electrode plate, and a separator placed between the positive electrode plate and the negative electrode plate. The positive electrode plate has a collector plate and a positive electrode active material layer formed on a surface of the collector plate. The negative electrode plate has a collector plate and a negative electrode active material layer formed on a surface of the collector plate. The positive electrode active material layer includes a positive electrode active material, a conductive agent and the like, and the negative electrode active material layer includes a negative electrode active material, a conductive agent and the like.

When the lithium-ion secondary battery is used as the cell 12, the collector plate of the positive electrode plate can be made of aluminum, and the collector plate of the negative electrode plate can be made of copper, for example. LiCo_{1/3}Ni_{1/3}Mn_{1/3}O₂ can be used as the positive electrode active material, and carbon can be used as the negative electrode active material, by way of example. The separator, the positive electrode active material layer, and the negative electrode active material layer are impregnated with an electrolytic solution. Instead of the use of the electrolytic solution, a solid electrolyte layer may be placed between the positive electrode plate and the negative electrode plate.

The current interrupt device 12b is used to break a current path within the cell 12. Specifically, the current interrupt device 12b can be operated to break the current path within the cell 12. For example, a fuse, a PTC (Positive Temperature Coefficient) element, or a current interrupting valve can be used as the current interrupt device 12b. These current interrupt devices 12b can be used individually or in combination.

The fuse serving as the current interrupt device 12b may be blown depending on the current passing through the fuse. The blown fuse can mechanically break the current path within the cell 12. This can prevent an excessive current from passing through the power-generating element 12a to protect the cell 12 (power-generating element 12a). The fuse serving as the current interrupt device 12b can be housed in the cell case or can be provided outside the cell case. When the fuse is provided outside the cell case, the fuse is provided for each of the cells 12 and is connected in series to the cell 12.

The PTC element serving as the current interrupt device 12b is placed on the current path in the cell 12, and increases the resistance as the temperature of the PTC element rises. As the current passing through the PTC element increases, the temperature of the PTC rises with Joule heat. In response to the temperature rise of the PTC element, the resistance of the PTC element is increased to enable the current in the PTC element to be interrupted. This can prevent an excessive current from passing through the power-generating element 12a to protect the cell 12 (power-generating element 12a).

The current interrupting valve serving as the current interrupt device 12b can be deformed upon an increase in internal pressure of the cell 12 to break the mechanical connection to the power-generating element 12a, thereby interrupting the current path within the cell 12. The cell 12 is hermetically sealed, and when gas is produced from the power-generating element 12a due to overcharge or the like, the internal pressure of the cell 12 is increased. The cell 12 (power-generating element 12a) is in an abnormal state during the production of the gas from the power-generating element 12a. In response to the increased internal pressure of the cell 12, the current interrupting valve can be deformed to break the mechanical connection to the power-generating element 12a. This can prevent a charge or discharge current from passing through the abnormal power-generating element 12a to protect the cell 12 (power-generating element 12a).

A monitor unit (corresponding to a voltage sensor) 20 shown in FIG. 1 detects the voltage of each of the battery blocks 11 and outputs the detection result to the controller 40. A temperature sensor 31 detects the temperature of each of the battery blocks 11 and outputs the detection result to the controller 40. The temperature sensor 31 can be provided for each of the battery blocks 11, or the single temperature sensor 31 can be provided for the assembled battery 10.

A current sensor 32 detects the value of a current passing through the assembled battery 10 and outputs the detection result to the controller 40. For example, in discharge of the assembled battery 10, a positive value can be used as the current value detected by the current sensor 32. In charge of the assembled battery 10, a negative value can be used as the current value detected by the current sensor 32. The current sensor 32 is only required to detect the value of the current passing through the assembled battery 10 and may be provided on the negative electrode line NL rather than on the positive electrode line PL. A plurality of current sensors 32 may be used. In view of the cost and size, the single current sensor 32 is preferably used for the single assembled battery 10 as in the present embodiment.

The controller 40 contains a memory 41 which stores a program for operating the controller 40 and particular information. The memory 41 may be provided outside the controller 40.

As described above, the value of the current passing through each of the battery blocks 11 can be detected by using the current sensor 32. Since the plurality of battery blocks 11 constituting the assembled battery 10 are connected in series, the value of the current passing through each of the battery blocks 11 can be detected by using the current sensor 32. The current value in this case is referred to as a detected current value.

The value of the current passing through each of the battery blocks 11 can be estimated on the basis of the voltage value of each of the battery blocks 11. The current value in this case is referred to as an estimated current value. A method of estimating the estimated current value is described later.

The detected current value Ir and the estimated current value Im have the relationship shown in the following expression (1).

$${I}_{m} = {I}_{r} \times \frac{N}{N - m} \qquad ( 1 )$$

In the expression (1), N represents the total number of the cells 12 constituting each of the battery blocks 11, and m represents the total number of the current interrupt devices 12b in an operational state (the number of interrupts) in each of the battery blocks 11. Since the current interrupt device 12b is provided for each of the cells 12, the number of interrupts m represents the total number of the cells 12 having the current interrupt devices 12b in the operational state. When none of the current interrupt devices 12b are operational in the battery block 11, the number of interrupts m is equal to zero.

When any current interrupt device 12b is operated, the internal resistance of the battery block 11 is increased in accordance with the number of the current interrupt devices 12b in the operational state. An internal resistance Ra of the battery block 11 before the operation of the current interrupt device 12b and an internal resistance Rb of the battery block 11 after the operation of the current interrupt device 12b have the relationship shown in the following expression (2).

$$Rb = Ra \times \frac{N}{N - m} \qquad ( 2 )$$

When any current interrupt device 12b is operational, the number of interrupts m is equal to or larger than one, and the value of N/(N-m) is larger than one, so that the internal resistance Rb is higher than the internal resistance Ra.

The estimated current value Im has the relationship shown in the following expression (3).

$${I}_{m} = \frac{{I}_{r} \times \frac{N}{N - m} R}{\frac{N}{N} R} \qquad ( 3 )$$

In the expression (3), R represents the internal resistance of the battery block 11. The numerator of the right side in the expression (3) corresponds to a voltage change amount ΔV of the battery block 11. The voltage change amount ΔV changes as the internal resistance of the battery block 11 changes. The voltage change amount ΔV is calculated from the OCV (Open Circuit Voltage) of the battery block 11 and the CCV (Closed Circuit Voltage) of the battery block 11 detected by the monitor unit 20.

Since the number of interrupts m is unknown, the value of the numerator of the right side in the expression (3) can not be calculated from the number of interrupts m. As described above, however, the value of the numerator of the right side in the expression (3) can be specified by detecting the voltage value of the battery block 11.

The OCV of the battery block 11 is the voltage of the battery block 11 when the assembled battery 10 (battery block 11) is not connected to a load. The CCV of the battery block 11 is the voltage of the battery block 11 when the assembled battery 10 (battery block 11) is connected to a load. The OCV and the CCV of the battery block 11 have the relationship shown in the following expression (4) in discharge of the battery block 11. A discharge current value is set to a positive value, and a charge current value is set to a negative value.

OCV=CCV+IR (4)

In the expression (4), I represents the value of a current passing through the battery block 11 and corresponds to the detected current value Ir. R represents the internal resistance of the battery block 11 and has an internal resistance value associated with the number of interrupts m when the current interrupt device 12b is operational. When the expression (4) is transformed, the following expression (5) can be provided. The expression (5) corresponds to the numerator of the right side in the expression (3).

IR=OCV−CCV=ΔV (5)

The denominator of the right side in the expression (3) is the internal resistance of the battery block 11 previously calculated by experiment or the like when any current interrupt device 12b is not operational (when the number of interrupts m is equal to zero). In estimating the estimated current value Im, the internal resistance (=R×N/N) previously calculated when the number of interrupts m is equal to zero is used as the internal resistance of the battery block 11 since the number of interrupts m is unknown. Since the internal resistance may depend on the temperature of the battery block 11 and the SOC (State of Charge) of the battery block 11, the internal resistance in accordance with the temperature and the SOC can be previously calculated. In this case, the internal resistance can be specified by specifying the temperature and the SOC. The SOC represents the ratio of the presently charged capacity to the full charge capacity of the battery block 11.

The expression (3) can be transformed into the following expression (6).

$${I}_{m} = {I}_{r} \times \frac{N}{N - m} \qquad ( 6 )$$

When any current interrupt device 12b is not operational, that is, when the number of interrupts m is equal to zero, the estimated current value Im is equal to the detected current value Ir in the expression (6). On the other hand, when any current interrupt device 12b is operational, the estimated current value Im is different from the detected current value Ir. The relationship between the estimated current value Im and the detected current value Ir is changed in accordance with the number of interrupts m.

When the estimated current value Im and the detected current value Ir obtained at the same time are compared, the number of interrupts m can be calculated on the basis of the expression (6). Since N shown in the expression (6) is a fixed value, the number of interrupts m can be calculated by obtaining the estimated current value Im and the detected current value Ir.

The detected current value Ir contains a detection error of the current sensor 32. Since the detection error of the current sensor 32 is a fixed value, the proportion of the detection error contained in the detected current value Ir is higher as the detected current value Ir is smaller. In other words, as the detected current value Ir is higher, the proportion of the detection error contained in the detected current value Ir can be reduced. Thus, the number of interrupts m is calculated by using the highest possible value of the detected current value Ir, so that the calculation of the number of interrupts m can be performed with a reduced influence of the detection error of the current sensor 32.

In view of the influence of noise contained in the detected current value Ir, it is preferable to specify the detected current value Ir in consideration of the changes of the current value detected by the current sensor 32 for a predetermined time period, rather than to use the instantaneous current value detected by the current sensor 32 as the detected current value Ir. For example, a value which can be used as the detected current value Ir is calculated by the mean square of the current values detected for the predetermined time period.

When the number of interrupts m is increased from zero, the operation of the current interrupt device 12b can be determined in the battery block 11. The number of interrupts m can be used to specify the number of the current interrupt devices 12b in the operational state. Since the current interrupting valve or the fuse serving as the current interrupt device 12b mechanically breaks the current path, the number of interrupts m is only increased. On the other hand, the PTC element serving as the current interrupt device 12b breaks the current path or continues the current path depending on the temperature of the PTC element. Thus, the number of interrupts m is increased or reduced.

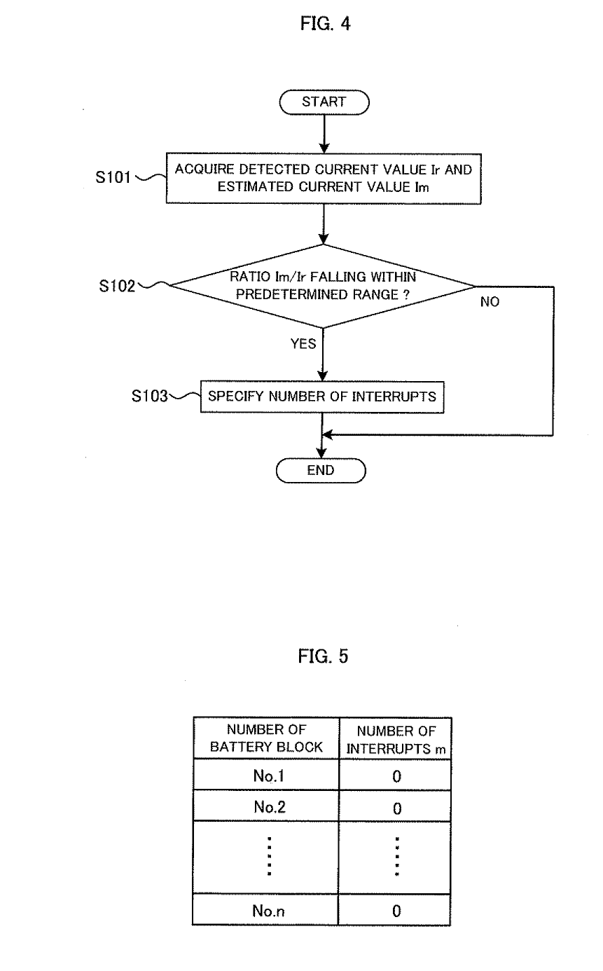

FIG. 4 is a flow chart showing processing of specifying the number of interrupts m. The processing shown in FIG. 4 is performed by the controller 40 at predetermined intervals. The processing of specifying the number of interrupts m is performed for each of the battery blocks 11.

At step S101, the controller 40 acquires the detected current value Ir based on the output from the current sensor 32. In addition, the controller 40 uses the voltage value of each of the battery blocks 11 detected by the monitor unit 20 to calculate the estimated current value Im. Processing of calculating the estimated current value Im is described later.

At step S102, the controller 40 determines whether or not the ratio between the detected current value Ir and the estimated current value Im acquired at step S101 falls within a predetermined range. Specifically, the controller 40 determines whether or not the ratio between the detected current value Ir and the estimated current value Im satisfies the condition shown in the following expression (7).

$$\frac{N}{N - m} \times ( 1 - α ) \leq \frac{{I}_{m}}{{I}_{r}} \leq \frac{N}{N - m} \times ( 1 + α ) \qquad ( 7 )$$

In the expression (7), α represents a tolerance value for specifying an allowable error and can be set as appropriate in a range smaller than one. Information about the tolerance α can be stored in the memory 41. Since the detected current value Ir contains the detection error of the current sensor 32 and noise and the estimated current value Im contains an estimation error, the ratio (Im/Ir) may not be coincident with the value (N/(N−m)). In the present embodiment, the tolerance α can be set in light of the error and the noise. Alternatively, the tolerance α may not be set, and in this case, the tolerance α is equal to zero.

The tolerance α can be changed in accordance with the number N. Specifically, as the number N is increased, the tolerance α can be reduced. In other words, the tolerance α can be increased as the number N is reduced. As the number N is increased, the proportion of each of the cells 12 in the total number N of the cells 12 constituting the battery block 11 is reduced. Thus, as the number N is increased, the value (N/(N−m)) is changed less, and the tolerance α can be reduced as the number N is increased. Since the number N is set previously in arranging the assembled battery 10, the tolerance α may be previously determined on the basis of the number N.

Since the number of interrupts m is zero or a positive integer, the controller 40 can calculate the value of N/(N−m) while changing the number of interrupts m. The controller 40 determines whether or not the ratio (Im/Ir) satisfies the condition shown in the expression (7) for the calculated value (N/(N−m)). The number m when the ratio (Im/Ir) satisfies the condition shown in the expression (7) is the total number (the number of interrupts) of the current interrupt devices 12b in the operational state in the battery block 11.

When the ratio (Im/Ir) satisfies the condition shown in the expression (7), the controller 40 proceeds to processing at step S103. On the other hand, when the ratio (Im/Ir) does not satisfy the condition shown in the expression (7), the controller 40 ends the processing shown in FIG. 4.

At step S103, the controller 40 specifies the number m when the ratio (Im/Ir) satisfies the condition shown in the expression (7) as the number of interrupts m.

After the specification of the number of interrupts m, the controller 40 can control charge and discharge of the assembled battery 10 based on the number of interrupts m.

When any current interrupt device 12b is operated in the battery block 11, no current passes through the cell 12 having the current interrupt device 12b in the operational state. A current, which would pass through the cell 12 having the current interrupt device 12b in the operational state, passes through the other cell 12 connected in parallel to the cell 12 having the current interrupt device 12b in the operational state. When the value of the current Is passing through the assembled battery 10 (battery block 11) is not limited, the value of the current passing through the other cell 12 is Is/(N−m). Since the value of (N-m) is lower than the number of N, the value of the current passing through the other cell 12 is increased.

When the value of the current passing through the cell 12 is increased, that is, when the current load on the cell 12 is increased, high rate deterioration may occur. When the lithium-ion secondary battery is used as the cell 12, lithium may be precipitated. In addition, the increase in the value of the current passing through the cell 12 easily operates the current interrupt device 12b.

Once the number of interrupts in is specified, the controller 40 can determine a current command value which controls charge and discharge of the assembled battery 10 based on the number of interrupts m. Specifically, the controller 40 can use the current command value to reduce the charge or discharge current of the assembled battery 10 in response to an increase in the number of interrupts m. The controller 40 can set the current command value based on the following expression (8).

$${I}_{S} ( 2 ) = {I}_{S} ( 1 ) \times \frac{N - m}{N} \qquad ( 8 )$$

In the expression (8), Is(1) represents the current command value before the current interrupt device 12b is operated, and Is(2) represents the current command value after the current interrupt device 12b is operated. As apparent from the expression (8), the value of (N−m)/N is lower than one when the number of interrupts m is equal to or higher than one, so that the current command value Is(2) is lower than the current command value Is(1).

The controller 40 can control the charge and discharge of the assembled battery 10 based on the current command value Is(2). Specifically, the controller 40 reduces the upper limit power to which the charge of the assembled battery 10 is allowed or reduces the upper limit power to which the discharge of the assembled battery 10 is allowed, on the basis of the current command value Is(2). For reducing the upper limit power, the upper limit power before the reduction can be multiplied by the value of (N−m)/N. The reduction in the upper limit powers to which the charge and discharge of the assembled battery 10 are allowed can limit the value of the current passing through the assembled battery 10 (cell 12).

When the number of interrupts m is N, the current interrupt devices 12b are operational in all the cells 12 constituting the battery block 11 and no current can be passed through the assembled battery 10. Thus, when the number of interrupts m approaches N, the controller 40 can prevent the charge and discharge of the assembled battery 10. Specifically, the controller 40 can set 0 kW for the upper limit powers to which the charge and discharge of the assembled battery 10 are allowed. The controller 40 can also turn off the system main relays SMR-B, SMR-G, and SMR-P.

The charge and discharge control for the assembled battery 10 can be performed not only during the operation of the battery system shown in FIG. 1 but also during supply of the power of an external power source to the assembled battery 10 or during supply of the power of the assembled battery 10 to an external device. The external power source refers to a power source provided outside the vehicle and can be provided by using a commercial power source, for example. The external device refers to an electronic device placed outside the vehicle and operated on the power received from the assembled battery 10. For example, a household electrical appliance can be used as the external device.

A charger can be used in supplying the power of the external power source to the assembled battery 10. The charger can convert an AC power from the external power source into a DC power and supply the DC power to the assembled battery 10. The charger can be mounted on the vehicle or can be provided outside the vehicle independently of the vehicle. In view of the voltage of the external power source and the voltage of the assembled battery 10, the charger can convert the voltage value. The controller 40 can control the operation of the charger to reduce the current value (charge current) of the assembled battery 10.

A power feeding apparatus can be used in supplying the power of the assembled battery 10 to the external device. The power feeding apparatus can convert a DC power from the assembled battery 10 into an AC power and supply the AC power to the external device. In view of the voltage of the assembled battery 10 and the operational voltage of the external device, the power feeding apparatus can convert the voltage value. The controller 40 can control the operation of the power feeding apparatus to reduce the current value (discharge current) of the assembled battery 10.

The limitation of the value of the current passing through the assembled battery 10 in accordance with the number of interrupts m can prevent an increase in current load on the cell 12. In addition, the value of the current passing through the non-operational current interrupt device 12b can be limited to prevent the current interrupt device 12b from being operated easily.

Since the charge and discharge of the assembled battery 10 can be controlled in accordance with the number of interrupts m in the present embodiment, the charge and discharge control for the assembled battery 10 can be performed efficiently. Only the detection of the operational state of the current interrupt device 12b may excessively limit the charge and discharge of the assembled battery 10. In contrast, the determination of the number of interrupts m can be performed to limit the charge and discharge of the assembled battery 10 in accordance with the number of interrupts m, so that the excessive limitation of the charge and discharge of the assembled battery 10 can be suppressed.

Next, the method of calculating the estimated current value Im is described. The estimated current value Im is only required to be calculated with the voltage value of the battery block 11 detected by the monitor unit 20, and the calculation method is not limited to the method described below.

A method of calculating the estimated current value Im is described.

The estimated current value Im can be calculated by using the voltage value of the battery block 11 detected by the monitor unit 20, the OCV associated with the SOC of the battery block 11 estimated in the previous processing, and the internal resistance of the battery block 11 determined previously by experiment or the like. The value determined by subtracting the OCV from the detected voltage value of the battery block 11 can be divided by the internal resistance to calculate the estimated current value Im. Since the internal resistance of the battery block 11 may depend on the temperature and the SOC of the battery block 11, the internal resistance in accordance with the temperature and the SOC can be previously determined. In this case, the internal resistance can be specified by specifying the temperature and the SOC. The internal resistance in accordance with the temperature and the SOC can be stored as a map or a function in the memory.

In the first processing of calculating the estimated current value Im, the voltage value of the battery block 11 detected by the monitor unit 20 can be used as the OCV of the battery block 11. The SOC of the battery block 11 at present can be estimated by summing the estimated current values Im. Japanese Patent Laid-Open No. 2008-243373, for example, has described a technology in which the estimated current value Im is calculated with a battery model. Under the condition that ΔV and IR can be assumed to be equal, the battery model can be used to calculate the estimated current value Im.

It is known that the cell 12 is worn and deteriorated over time. Thus, when the estimated current value Im is calculated, the resistance used in the calculation of the estimated current value Im can be corrected in accordance with the wear deterioration. For example, an experiment can be previously conducted to acquire a resistance change rate of the battery block 11 (cell 12). The resistance change rate is a value provided by dividing the resistance of the battery block 11 in the deteriorated state by the resistance of the battery block 11 in the initial state.

The initial state is the state in which the battery block 11 is not deteriorated, and refers to the state immediately after the battery block 11 is manufactured, for example. When the battery block 11 is deteriorated, the resistance of the battery block 11 is increased, and the resistance change rate is increased from one as the initial value. The resistance before the correction is multiplied by the present resistance change rate, and the result can be used as the resistance used in the calculation of the estimated current value Im.

In specifying the internal resistance of the battery block 11 used in the calculation of the estimated current value Im based on the SOC of the battery block 11, the SOC of the battery block 11 needs to be estimated accurately. The SOC of the battery block 11 can be estimated by using the estimated current value Im.

First, the estimated current values Im can be summed for a predetermined time period to calculate a sum value ΣIm. Assuming that the full charge capacity of the battery block 11 is Cf, a change amount ΔSOC of the SOC of the battery block 11 is represented as the following expression (9).

$$Δ SOC = \frac{\sum {I}_{m}}{Cf} \times 100 \qquad ( 9 )$$

The calculated change amount ΔSOC can be added to the SOC of the battery block 11 before the calculation of the change amount ΔSOC to provide the present SOC of the battery block 11. When any current interrupt device 12b is operational, the full charge capacity Cf of the battery block 11 is changed in accordance with the number of interrupts m. Specifically, as the number of interrupts m is increased, the full charge capacity Cf of the battery block 11 is reduced.

Assuming that the full charge capacity of the battery block 11 before the operation of the current interrupt device 12b is Cf1 and the full charge capacity of the battery block 11 after the operation of the current interrupt device 12b is Cf2, the full charge capacities Cf1 and Cf2 have the relationship shown in the following expression (10).

$$Cf 2 = C f 1 \times \frac{N - m}{N} \qquad ( 10 )$$

In the expression (10), N represents the number of the cells 12 constituting the battery block 11, and m represents the number of interrupts. Once the number of interrupts m is found, the full charge capacity Cf can be changed in accordance with the number of interrupts m in calculating the change amount ΔSOC with the expression (9).

As described in Embodiment 1, the estimated current value Im and the detected current value Ir have the relationship shown in the expression (6). When the expression (6) is considered, the summed value ΣIm of the estimated current values Im is calculated by multiplying the summed value ΣIr of the detected current values Ir by N/(N−m). In the expression (9), the full charge capacity Cf is set to the initial value, that is, the full charge capacity of the battery block 11 not including current interrupt device 12b in the operational state. The change amount ΔSOC in this case can be represented by the following expression (11).

$$\begin{matrix}\begin{matrix}Δ SOC = \frac{\sum {I}_{r} \times \frac{N}{N - m}}{Cf} \times 100 \\ = \frac{\sum {I}_{r}}{Cf} \times \frac{N}{N - m} \times 100\end{matrix} & ( 11 ) \\ \begin{matrix}Δ SOC = \frac{\sum {I}_{r}}{Cf 2} \times 100 \\ = \frac{\sum {I}_{r}}{Cf 1 \times \frac{N - m}{N}} \times 100 \\ = \frac{\sum {I}_{r}}{Cf 1} \times \frac{N}{N - m} \times 100\end{matrix} & ( 12 )\end{matrix}$$

The above expression (11) is similar to the expression (12) for calculating the change amount ΔSOC by using the summed value ΣIr of the detected current values Ir and the value of the full charge capacity of the battery block 11 changed in accordance with the number of interrupts m. The change amount ΔSOC calculated from the summed value ΣIr of the detected current values Ir and the full charge capacity in accordance with the number of interrupts m is equal to the change amount ΔSOC calculated from full charge capacity held at the initial value and the summed value ΣIm of the estimated current values Im.

For this reason, when the estimated current value Im is used in calculating the change amount ΔSOC, the change amount ΔSOC in accordance with the number of interrupts m can be calculated without changing the full charge capacity Cf of the battery block 11 in accordance with the number of interrupts m. In other words, the change amount ΔSOC can be estimated accurately only by summing the estimated current values Im with the full charge capacity Cf of the battery stack 11 held at the initial value.

It is known that the error in estimating the estimated current value Im generally contains no offset component and that the SOC error characteristically approaches zero when the estimated current values Ira are summed over a long time period. Thus, the use of the estimated current value Im in the estimation of the change amount ΔSOC can improve the accuracy of the estimation of the change amount ΔSOC.

As described in Embodiment 1, the estimated current value Im can be corrected in accordance with the deterioration (resistance change) of the battery block 11 (cell 12) in the calculation of the estimated current value Im. The full charge capacity of the battery block 11 is reduced when the battery block 11 is deteriorated, so that the full charge capacity of the battery block 11 can be corrected in accordance with the deterioration of the battery block 11.

Specifically, the capacity retention rate of the battery block 11 can be first acquired by previously conducting an experiment. The capacity retention rate is a value provided by dividing the full charge capacity of the battery block 11 in the deteriorated state by the full charge capacity of the battery block 11 in the initial state. As the battery block 11 is more deteriorated, the capacity retention rate is reduced from one as the initial value. In calculating the change amount ΔSOC, the full charge capacity as the initial value is multiplied by the capacity retention rate in accordance with the present time, and the result can be used as the full charge capacity Cf shown in the expression (9).

The correction of the estimated current value Im and the full charge capacity Cf in light of the deterioration of the battery block 11 can improve the accuracy of the estimation of the SOC of the battery block 11.

In addition of the calculation of the SOC of the battery block 11 from the estimated current value Im, the SOC of the battery block 11 can be calculated from the detected current value Ir. The resulting two SOCs can be weighed to estimate the SOC of the battery block 11. For example, the weight for the SOC calculated from the estimated current value Im can be higher than the weight for the SOC calculated from the detected current value Ir.

The full charge capacity Cf of the battery block 11 needs to be corrected in accordance with the number of interrupts m in the calculation of the SOC from the detected current value Ir. In this case, the number of interrupts m needs to be previously specified. The detected current value Ir acquired for a short time period can be used as the detected current value Ir in the calculation of the SOC from the detected current value Ir. The short time period allows a reduction in error component contained in the detected current value Ir.

### Embodiment 2

A battery system which is Embodiment 2 of the present invention will hereinafter be described. Members having the same functions as those of the members described in Embodiment 1 are designated with the same reference numerals and detailed description thereof is omitted. The following description is mainly focused on differences from Embodiment 1.

In Embodiment 1, the number of interrupts m is calculated by comparing the detected current value Ir and the estimated current value Im acquired at the same time in each of the battery blocks 11. In the present embodiment, the number of interrupts m is calculated by comparing estimated current values Im in arbitrary two of a plurality of battery blocks 11 constituting an assembled battery 10.

In general, a current interrupt device 12b is not operated frequently. Thus, the plurality of battery blocks 11 constituting the assembled battery 10 include both of a battery block 11 including a current interrupt device 12b in an operational state and a battery block 11 including no current interrupt device 12b in the operational state. The number of interrupts m can be calculated by comparing the estimated current value Im of the battery block 11 including no current interrupt device 12b in the operational state and the estimated current value Im of the battery block 11 including the current interrupt device 12b in the operational state.

As described in Embodiment 1, the estimated current value Im of the battery block 11 including no current interrupt device 12b in the operational state is equal to the detected current value Ir. While the ratio (Im/Ir) is calculated in Embodiment 1, the detected current value Ir can be replaced with the estimated current value Im of the battery block 11 including no current interrupt device 12b in the operational state, that is, the estimated current value Im of the battery block 11 with the number of interrupts m equal to zero.

The determination of whether or not the current interrupt device 12b in the operational state is included in each of the battery blocks 11 may be performed by forming and referencing a map representing the correspondence between each of the battery blocks 11 and the number of interrupts m as shown in FIG. 5. The map shown in FIG. 5 shows the relationship between the number for specifying each of the battery blocks 11 and the number of interrupts m associated with each of the battery blocks 11.

The map shown in FIG. 5 can be stored in a memory 41. The initial value of the number of interrupts m is zero. When the number of interrupts m in a particular battery block 11 is a value larger than zero as a result of the calculation of the number of interrupts m, later described, the number of interrupts m associated with the particular battery block 11 in the map may be changed to the value after the calculation.

When a plurality of battery blocks 11 have the number of interrupts m equal to zero, the median estimated current value Im of the estimated current values Im of those battery blocks 11 can be specified, for example. The median refers to a value at the center of the estimated current values Im arranged in decreasing order of magnitude. Alternatively, a plurality of estimated current values Im included in a predetermined range with the median estimated current value. Im as the reference can be specified, and the average value of those estimated current values Im can be calculated. This value (median or average value) is used as the estimated current value (representative value) Im. The estimated current value (representative value) Im can be compared with the estimated current value Im of each of the battery blocks 11 to calculate the number of interrupts m.

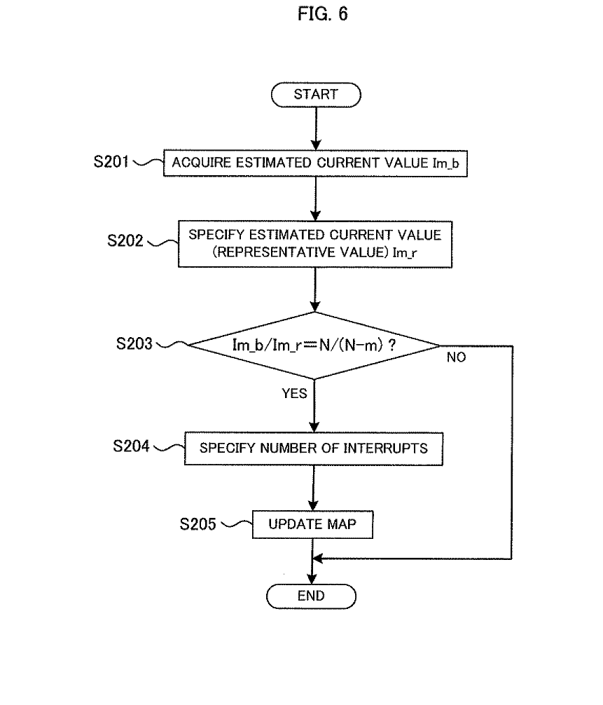

FIG. 6 is a flow chart showing processing of specifying the number of interrupts m in the present embodiment. The processing shown in FIG. 6 is performed by a controller 40 at predetermined intervals. The processing shown in FIG. 6 is performed for each of the battery blocks 11.

At step S201, the controller 40 calculates an estimated current value Im_b of each of the battery blocks 11. The estimated current value Im_b can be calculated with the method described in Embodiment 1. At step S202, the controller 40 specifies an estimated current value (representative value) Im_r. The estimated current value (representative value) Im_r can be specified with the method described above.

At step S203, the controller 40 uses the estimated current value (representative value) Im_r and the estimated current value (comparative value) Im_b of each of the battery blocks 11 to determine whether or not any current interrupt device 12b is operational in each of the battery blocks 11. Specifically, the controller 40 determines whether or not the estimated current value (representative value) Im_r and the estimated current value (comparative value) Im_b satisfy the condition in the following expression (13).

$$\frac{{I}_{m \_ b}}{{I}_{m - r}} = \frac{N}{N - m} \qquad ( 13 )$$

The controller 40 calculates the value of N/(N−m) while changing the number m, and determines whether or not the calculated value (N/(N−m)) is equal to the ratio (Imb/Im_r). When the calculated value (N/(N−m)) is equal to the ratio (Im_b/Im_r), the controller 40 proceeds to processing at step S204. When the calculated value (N/(N−m)) is different from the ratio (Im_b/Im_r), the controller 40 ends the processing shown in FIG. 6.

When an estimation error of the estimated current value Im or variations in deterioration among the plurality of battery blocks 11 occur, the ratio (Im_b/Im_r) may not be coincident with the calculated value (N/(N−m)). Thus, a tolerance β can be set to determine whether or not the ratio (Im_b/Im_r) satisfies the condition in the following expression (14). Information about the tolerance β can be stored in a memory 41.

$$\frac{N}{N - m} \times ( 1 - β ) \leq \frac{{I}_{m \_ b}}{{I}_{m - r}} \leq \frac{N}{N - m} \times ( 1 + β ) \qquad ( 14 )$$

The tolerance β can be changed in accordance with the number N. Specifically, as the number N is increased, the tolerance β can be reduced. In other words, the tolerance β can be increased as the number N is reduced. As the number N is increased, the proportion of each of cells 12 in the total number N of the cells 12 constituting the battery block 11 is reduced. Thus, as the number N is increased, the value (N/(N−m)) is changed less, and the tolerance β can be reduced as the number N is increased. Since the number N is set previously in arranging the assembled battery 10, the tolerance β may be previously determined on the basis of the number N.

When the ratio (Im_b/Im_r) satisfies the condition in the expression (14), the controller 40 can proceed to processing at step S204. When the ratio (Im_b/Im_r) does not satisfy the condition in the expression (14), the controller 40 can end the processing shown in FIG. 6.

At step 3204, the controller 40 specifies the number m when the calculated value (N/(N−m)) is equal to the ratio (Im_b/Im_r), as the number of interrupts m. At step S205, the controller 40 compares the number of interrupts m stored in the map in FIG. 5 with the number of interrupts m calculated at step S204 in each of the battery blocks 11, and changes the number of interrupts m stored in the map of FIG. 5 to the number of interrupts m calculated at step S204 when those numbers of interrupts m are different from each other. On the other hand, when the number of interrupts m stored in the map of FIG. 5 is equal to the number of interrupts m calculated at step S204, the number of interrupts m stored in the map of FIG. 5 is maintained.

When the fuse or the current interrupting valve is used as the current interrupt device 12b, the number of interrupts m is only increased. In the map of FIG. 5, the number of interrupts m associated with each of the battery blocks 11 is increased in response to the operation of the current interrupt device 12b. When the PTC element is used as the current interrupt device 12b, the number of interrupts m is increased or reduced as described above. The number of interrupts m associated with the battery block 11 is increased or reduced in the map of FIG. 5.

According to the present embodiment, the number of interrupts m can be specified by using only the estimated current value Im. When the number of interrupts m is changed from zero to a positive integer, it can be determined that any current interrupt device 12b is operated in the battery block 11. The detected current value Ir contains the detection error of the current sensor 32 or noise. In the present embodiment, however, the detected current value Ir is not used, and the influence of the detection error and the noise can be eliminated.

The number of interrupts m associated with each of the battery blocks 11 is stored in the map shown in FIG. 5. When the number of interrupts m is not changed, the relationship in the following expression (15) is satisfied.

$$\frac{{I}_{m \_ b}}{{I}_{m - r}} \times \frac{N - m}{N} = 1 \qquad ( 15 )$$

As shown in the expression (13), the ratio (Im_b/Im_r) is equal to the value (N/(N−m)). Thus, the ratio (Im_b/Imr) can be multiplied by the inverse of the value (N/(N−m)) to provide a calculated value equal to one, which means that the relationship in the expression (15) holds. The estimated current values Im_b and Im_r shown in the expression (15) represent values acquired at the present processing. In the expression (15), m represents the number of interrupts m stored in the map of FIG. 5 to the previous processing.

When the number of interrupts in is not changed between the previous processing and the present processing, the relationship in the expression (15) holds. Thus, it can be determined whether or not the number of interrupts m is changed by determining whether or not the relationship in the expression (15) is satisfied. When the number of interrupts m is increased, the value calculated by multiplying the ratio (Im_b/Im_r) by the value ((N−m/N) is larger than one. When the number of interrupts m is reduced, the value calculated by multiplying the ratio (Im_b/Im_r) by the value ((N−m/N) is smaller than one.

When any of the current interrupt devices 12b is additionally operated in the present processing, the ratio (Im_b/Im_r) is represented by the following expression (16).

$$\frac{{I}_{m \_ b}}{{I}_{m - r}} \times \frac{N}{N - {m}^{′}} \qquad ( 16 )$$

In the expression (16), m′ represents the number of interrupts including the additionally operated current interrupt device 12b and is different from the number of interrupts m stored in the map. In this case, the relationship in the expression (15) does not hold, and it can be determined that the additional current interrupt device 12b is operational.

Since the estimated current value Im may contain the estimation error, the value calculated by multiplying the ratio (Im_b/Im_r) by the value ((N−m)/N) may be deviated from one. Thus, a tolerance γ can be set to determine whether or not the ratio (Im_b/Im_r) satisfies the condition in the following expression (17). Information about the tolerance γ can be stored in the memory 41.

$$( 1 - γ ) \leq \frac{{I}_{m \_ b}}{{I}_{m - r}} \times \frac{N - m}{N} \leq ( 1 + γ ) \qquad ( 17 )$$

The tolerance γ can be changed in accordance with the number N. Specifically, as the number N is increased, the tolerance γ can be reduced. In other words, the tolerance γ can be increased as the number N is reduced. As the number N is increased, the proportion of each of the cells 12 in the total number N of the cells 12 constituting the battery block 11 is reduced. Thus, as the number N is increased, the value (N−m)/N) is changed less, and the tolerance γ can be reduced as the number N is increased. Since the number N is set previously in arranging the assembled battery 10, the tolerance γ may be previously determined on the basis of the number N.

When the value provided by multiplying the ratio (Im_b/Im_r) by the value ((N−m)/N) satisfies the condition of the expression (17), it can be determined that the number of interrupts m is not changed.

It can be determined whether or not the number of interrupts m is changed by first determining whether or not the condition shown in the expression (15) or the expression (17) is satisfied in each of the battery blocks 11. Then, the processing of calculating the number of interrupts m can be performed only for the battery block 11 in which it is determined that the number of interrupts m is changed.

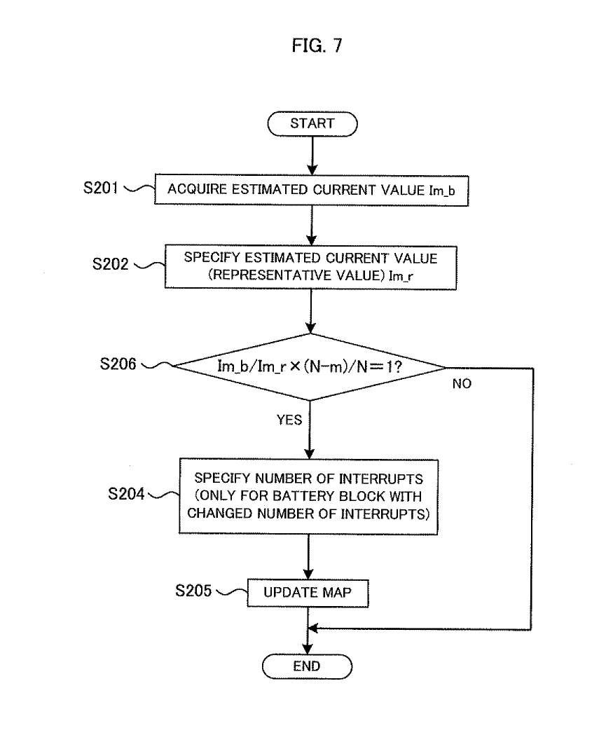

FIG. 7 shows the processing. In FIG. 7, processing identical to that described in FIG. 6 is designated with the same reference numeral and detailed description thereof is omitted. The processing shown in FIG. 7 differs from that in FIG. 6 only in the processing at step S203 shown in FIG. 6 and involves processing at step S206 instead of the processing at step S203.

At step S206, the controller 40 determines whether or not the condition in the expression (15) or the expression (17) is satisfied. When the condition in the expression (15) or the expression (17) is satisfied, the controller 40 proceeds to processing at step S204. When the condition in the expression (15) or the expression (17) is not satisfied, the controller 40 ends the processing shown in FIG. 7. At step S204, the calculation of the number of interrupts m is performed only for the battery block 11 in which it is determined that the number of interrupts m is changed.

1. An electric storage system comprising:
an electric storage block having a plurality of electric storage elements connected in parallel;
a voltage sensor detecting a voltage of the electric storage block; and
a controller determining a state of the electric storage block,
wherein each of the electric storage elements has a current interrupt device interrupting a current path within the electric storage element, and
the controller uses the voltage detected by the voltage sensor to calculate an estimated value of a current passing through the electric storage block, and
the controller uses a correspondence between a ratio between the estimated current value and a reference value of a current passing through the electric storage block and a ratio between the total number of the electric storage elements constituting the electric storage block and the total number of the current interrupt device not in an interrupt state to determine whether or not the current interrupt device is in the interrupt state.

2. The electric storage system according to claim 1, wherein the controller uses the correspondence to specify the total number of the current interrupt device in the interrupt state.

3. The electric storage system according to claim 1, wherein the controller determines that the current interrupt device is in the interrupt state when the following expression (I) is satisfied:
$$\frac{I 1}{I 2} \times \frac{N - m}{N} = 1 \qquad ( I )$$
in the expression (I), I1 represents the estimated current value, I2 represents the reference current value, N represents the total number of the electric storage elements constituting the electric storage block, and m represents the total number of the current interrupt device in the interrupt state.

4. The electric storage system according to claim 1, further comprising a current sensor detecting a value of a current passing through the electric storage block,
wherein the reference current value is the value of the current detected by the current sensor.

5. The electric storage system according to claim 1, wherein a plurality of the electric storage blocks are connected in parallel, and
the reference current value is the estimated current value in the electric storage block which does not include the current interrupt device in the interrupt state.

6. The electric storage system according to claim 5, further comprising a memory storing information indicating a correspondence between each of the electric storage blocks and the total number of the current interrupt device in the interrupt state, and
the controller uses the information stored in the memory to specify the electric storage block which does not include the current interrupt device in the interrupt state.

7. The electric storage system according to claim 5, wherein, when two or more of the electric storage blocks do not include the current interrupt device in the interrupt state, the reference current value is a median of the estimated current values in the two or more electric storage blocks or a value calculated by averaging two or more of the estimated current values included in a predetermined range with the median as a reference.

8. The electric storage system according to claim 1, wherein the current interrupt device is a fuse interrupting the current path through blowing, a PTC element interrupting the current path through an increased resistance associated with a temperature rise, or a current interrupting valve deformed upon an increased internal pressure of the electric storage element to break the current path.

9. A method of determining a state of an electric storage block having a plurality of electric storage elements connected in parallel, each of the electric storage elements having a current interrupt device interrupting a current path within the electric storage element, the method comprising:
using a voltage detected by a voltage sensor to calculate an estimated value of a current passing through the electric storage block, and
using a correspondence between a ratio between the estimated current value and a reference value of a current passing through the electric storage block and a ratio between the total number of the electric storage elements constituting the electric storage block and the total number of the current interrupt device not in a interrupt state to determine whether or not the current interrupt device is in the interrupt state.

10. The electric storage system according to claim 2, wherein the controller determines that the current interrupt device is in the interrupt state when the following expression (I) is satisfied:
$$\frac{I 1}{I 2} \times \frac{N - m}{N} = 1 \qquad ( I )$$
in the expression (I), I1 represents the estimated current value, I2 represents the reference current value, N represents the total number of the electric storage elements constituting the electric storage block, and m represents the total number of the current interrupt device in the interrupt state.

11. The electric storage system according to claim 3, further comprising a current sensor detecting a value of a current passing through the electric storage block,
wherein the reference current value is the value of the current detected by the current sensor.

12. The electric storage system according to claim 3, wherein a plurality of the electric storage blocks are connected in parallel, and
the reference current value is the estimated current value in the electric storage block which does not include the current interrupt device in the interrupt state.

13. The electric storage system according to claim 12, further comprising a memory storing information indicating a correspondence between each of the electric storage blocks and the total number of the current interrupt device in the interrupt state, and
the controller uses the information stored in the memory to specify the electric storage block which does not include the current interrupt device in the interrupt state.

14. The electric storage system according to claim 6, wherein, when two or more of the electric storage blocks do not include the current interrupt device in the interrupt state, the reference current value is a median of the estimated current values in the two or more electric storage blocks or a value calculated by averaging two or more of the estimated current values included in a predetermined range with the median as a reference.
